(19) United States
(12) Patent Application Publication
(10) Pub. No.: US 2024/0397787 A1
(43) Pub. Date: Nov. 28, 2024

(54) DISPLAY DEVICE AND METHOD OF MANUFACTURING THE SAME

(71) Applicant: Samsung Display Co., Ltd., Yongin-si (KR)

(72) Inventors: Chun Gi YOU, Yongin-si (KR); Sang Yeol KIM, Yongin-si (KR)

(21) Appl. No.: 18/599,659

(22) Filed: Mar. 8, 2024

(30) Foreign Application Priority Data
May 26, 2023 (KR) 10-2023-0068590

(51) Int. Cl. H10K 59/80; H10K 50/88; H10K 59/121; H10K 59/122; H10K 85/30

(52) U.S. Cl. CPC H10K 59/80518; H10K 50/88; H10K 59/121; H10K 59/122; H10K 85/30

(57) ABSTRACT

A display device includes: a substrate including a display area and a pad area located outside of the display area; reflective electrodes including a pad reflective electrode disposed in the pad area disposed on the substrate and spaced apart from each other; an inorganic layer disposed over the reflective electrodes; first pixel electrodes including a pad pixel electrode disposed in the pad area disposed on the first inorganic layer,; a pixel defining layer including a first opening above each of the first pixel electrodes disposed in the display area; and a separator disposed on the pixel defining layer. The inorganic layer includes a second opening extending to the pad reflective electrode. The pad pixel electrode is disposed in the second opening on the pad reflective electrode through the second opening. The separator extends to the pad area from the display area to be disposed directly on the pad pixel electrode.

### CROSS-REFERENCE TO RELATED APPLICATION

The present application claims priority, under 35 U.S.C. § 119 (a), to Korean patent application No. 10-2023-0068590 filed on May 26, 2023 in the Korean Intellectual Property Office, the entire disclosure of which is incorporated herein by reference.

### BACKGROUND

### 1. Technical Field

The disclosure generally relates to a display device and a method of manufacturing the same.

### 2. Related Art

An organic light emitting diode (OLED) is an active light emitting display element, and has not only advantages of having a wide viewing angle and being excellent in contrast but also advantages of being able to be driven at a low voltage, being lightweight and thin, and having a high response speed. Accordingly, OLED is receiving much attention as a next-generation display element.

A display device including OLED typically includes a display area and a pad area at an outer portion of the display area. A plurality of pixels are disposed in the display area, and each of the pixels includes an OLED and a pixel circuit electrically connected thereto. A plurality of pads connected to ends of lines to transfer an electrical signal to the display area may be located in the pad area. In addition, tests for checking whether the pixel circuit is electrically operated, and the like may be performed in the pad area so as to ensure the reliability of the display device.

### SUMMARY

The disclosure pertains to a pad structure disposed in a pad area that is separate from a display area, is the pad area providing a display device having improved reliability.

Embodiments also provide a method of manufacturing the display device having the pad structure.

In accordance with an aspect of the disclosure, there is provided a display device including: a substrate including a display area and a pad area located outside of the display area; reflective electrodes disposed on the substrate and spaced apart from each other in a first direction, the reflective electrodes including a pad reflective electrode disposed in the pad area; an inorganic layer disposed over the reflective electrodes; first pixel electrodes disposed on the first inorganic layer, the first pixel electrodes including a pad pixel electrode disposed in the pad area; a pixel defining layer including a first opening above each of the first pixel electrodes disposed in the display area; and a separator disposed on the pixel defining layer of the display area and on the pad area, wherein the inorganic layer includes a second opening extending to the pad reflective electrode, wherein the pad pixel electrode is disposed in the second opening and contacts the pad reflective electrode through the second opening, and wherein the separator continuously extends to the pad area from the display area to be disposed directly on the pad pixel electrode.

In a plan view, the first pixel electrodes may be disposed on the reflective electrodes.

The separator may cover the pad pixel electrode.

The display device may include: a via layer disposed between the substrate and the reflective electrodes, the via layer having a contact hole in the pad area; and a pad electrode electrically connected to the pad reflective electrode through the contact hole. The contact hole may overlap with the second opening.

The pad reflective electrode may include: a first pad reflective electrode disposed on the via layer, the first pad reflective electrode including a first conductive material; and a second pad reflective electrode disposed on the first pad reflective electrode, the second pad including a second conductive material different from the first conductive material.

The first pad reflective electrode may cover the pad electrode and extend beyond the boundary of the pad electrode. The via layer may include an inorganic material.

The first pad reflective electrode may include titanium (Ti), and the second pad reflective electrode may include aluminum (Al).

The display device may further include a barrier layer disposed between the first pad reflective electrode and the pad electrode in the contact hole. The barrier layer may include a metal compound.

The barrier layer may include titanium nitride (TiN).

The pixel defining layer may be disposed only outside of the pad area.

The separator may include a metal material.

The display device may further include: an organic light emitting part disposed on the pixel defining layer and the separator in the display area, the organic light emitting part including a plurality of light generation layers; and a second pixel electrode disposed on the organic light emitting part.

The display device may further include first, second, and third protective layers sequentially disposed on the second pixel electrode in a third direction intersecting the first direction. The first, second, and third protective layers may be disposed only outside of the pad area.

The organic light emitting part may include a hole injection layer, a hole transport layer, a light emitting layer, an electron transport layer, and an electron injection layer, which are sequentially disposed in the third direction.

In accordance with another aspect of the disclosure, there is provided a method of manufacturing a display device, the method including: forming a substrate including a display area and a pad area located at one side of the display area; forming a via layer on the substrate; forming a contact hole through the via layer in the pad area; forming a pad electrode in the contact hole; forming pad reflective electrodes spaced apart from each other in a first direction on the via layer; forming an inorganic layer, partially removing sections of the inorganic layer to form a second opening above at least one of the pad reflective electrodes disposed in the pad area; forming first pixel electrodes on the reflective electrodes; and forming a separator on a pad pixel electrode disposed in the pad area among the first pixel electrodes.

The display area may include first, second, and third sub-pixels. The method further includes: forming a pixel defining layer on the first pixel electrodes in the display area and on the pad area; and selectively removing the pixel defining layer from each of the first sub-pixel, the second sub-pixel, and the third sub-pixel in the display area and removing the pixel defining layer from the pad area from the pad area.

The partial removal of the pixel defining layer may further include forming a first opening exposing each of the first pixel electrodes in the display area. The method may further include sequentially forming an organic light emitting part and a second pixel electrode on the first pixel electrode that is exposed at the base of the first opening.

The method may further include: forming a first protective layer over the separator formed in the pad area and the second pixel electrode formed in the display area; and removing the first protective layer formed in the pad area.

The method may further include sequentially forming a second protective layer and a third protective layer in a third direction intersecting the first direction on the first protective layer in the display area. The first protective layer and the third protective layer may include an inorganic material, and the second protective layer may include an organic material.

The forming of the pad reflective electrode disposed in the pad area may include: forming a first pad reflective electrode including a first conductive material in an area overlapping with the contact hole on the via layer; and forming a second pad reflective electrode including a second conductive material different from the first conductive material on the first pad reflective electrode.

### BRIEF DESCRIPTION OF THE DRAWINGS

FIG. 1 is a schematic plan view illustrating a display device in accordance with embodiments of the disclosure.

FIG. 2 is a plan view illustrating an embodiment of a pixel shown in FIG. 1.

FIG. 3 is a circuit diagram illustrating an embodiment of a sub-pixel included in the pixel shown in FIG. 2.

FIG. 4 is a sectional view illustrating an embodiment of a light emitting element shown in FIG. 3.

FIG. 5 is a sectional view illustrating another embodiment of the light emitting element shown in FIG. 3.

FIG. 6 is a sectional view illustrating an embodiment of a pixel including the light emitting element shown in FIG. 4 or 5.

FIG. 7 is a plan view illustrating an embodiment of a pad area shown in FIG. 1.

FIG. 8 is a sectional view illustrating an embodiment of the pad area shown in FIG. 1.

FIGS. 9, 10, 11, 12, 13, 14, 15, and 16 are schematic sectional views illustrating a method of manufacturing the display device in accordance with embodiments of the disclosure.

### DETAILED DESCRIPTION

Hereinafter, exemplary embodiments of the disclosure will be described in more detail with reference to the accompanying drawings. Throughout the drawings, the same reference numerals are given to the same elements, and their overlapping descriptions will be omitted.

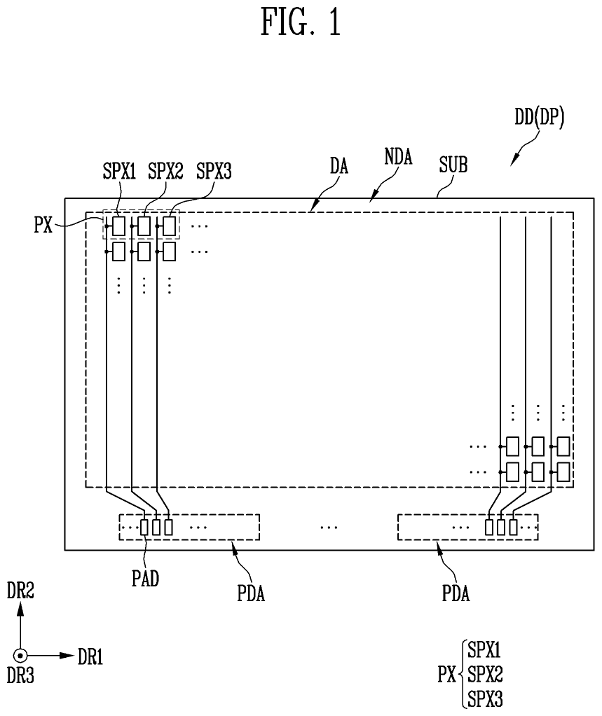

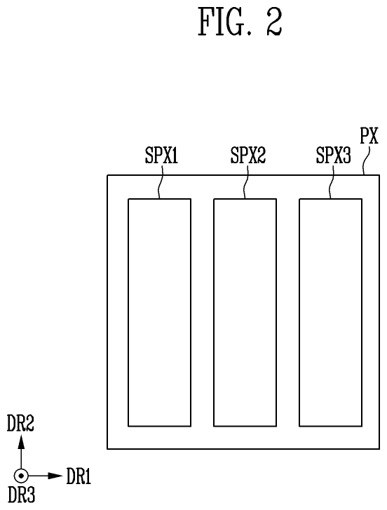

FIG. 1 is a schematic plan view illustrating a display device in accordance with embodiments of the disclosure. FIG. 2 is a plan view illustrating an embodiment of a pixel shown in FIG. 1. As shown in FIG. 1, the display device DD includes a display area DA, a non-display area NDA, and a pad area PDA. As will be described below, some layers are common to the display area DA and the pad area PDA, while other layers are only present in either the display area DA or the pad area PDA.

In FIG. 1, a structure of the display panel DP will be briefly illustrated based on the display area DA. However, in some embodiments, at least one driving circuit (e.g., at least one of a scan driver and a data driver), lines, and/or pads, which are not shown in the drawing, may be further disposed in the display panel DP.

The disclosure may be applied as long as the display device DD is an electronic device in which a display surface is applied to at least one surface thereof, such as a smartphone, a television, a tablet personal computer (PC), a mobile phone, a video phone, an electronic book reader, a desktop PC, a laptop PC, a netbook computer, a workstation, a server, a personal digital assistant, a portable multimedia player (PMP), an MP3 player, a medical device, a camera, or a wearable device.

Referring to FIG. 1, the display panel DP may include a substrate SUB and pixels PX provided on the substrate SUB.

The display panel DP may have various shapes. In an embodiment, the display panel DP may be provided in a rectangular plate shape, but the disclosure is not limited thereto. For example, the display panel DP may have a shape such as a circular shape or an elliptical shape. Also, the display panel DP may include an angular corner and/or a curved corner. For convenience, a case where the display panel DP has a rectangular plate shape is illustrated in FIG. 1. Also, in FIG. 1, an extending direction (e.g., a lateral direction) of long sides of the display panel DP is indicated as a first direction DR1, and an extending direction (e.g., a longitudinal direction) of short sides of the display panel DP is indicated as a second direction DR2.

The substrate SUB constitutes a base member of the display panel DP, and may be a rigid or flexible substrate or film. For example, the substrate SUB may be configured as a rigid substrate made of glass or tempered glass, a flexible substrate (or thin film) made of plastic or metal, or at least one insulating layer. The material and/or property of the substrate SUB is not particularly limited.

The substrate SUB (and the display panel DP) may include a display area DA for displaying an image and the non-display area NDA outside the display area DA. The display area DA may constitute a screen on which the image is displayed, and the non-display area NDA may be located on at least one side of the display area DA. For example, the non-display area NDA may surround the display area DA. However, the disclosure is not limited thereto.

The pixels PX may be disposed in the display area DA on the substrate SUB. The non-display area NDA may be disposed at the periphery of the display area DA. Various lines, pads, and/or a built-in circuit, which are connected to the pixels PX of the display area DA, may be disposed in the non-display are NDA. The non-display area NDA may include a pad area PDA, and pads PAD may be disposed in the pad area PDA. For example, the pads PAD may be connected to a driving circuit, such as a source driver or a timing controller, which is mounted on a flexible circuit board. In an embodiment, when the display panel DP is connected to a plurality of source drivers, the pad area PDA may correspond to each source driver, but the disclosure is not limited thereto.

The pixel PX may be connected to the pad PAD through a line, and receive a data signal from the driving circuit. When a built-in circuit (e.g., a gate driver) is provided in the display panel DP, the built-in circuit may be connected to the pad PAD. Although a case where the pads PAD (or the pad area PDA) is disposed at only a lower side of the display panel DP is illustrated in FIG. 1, the disclosure is not limited thereto. For example, the pads PAD may be respectively disposed at upper and lower sides of the display panel DP.

In the embodiments of the disclosure, the term “connection (or access)” may inclusively mean physical and/or electrical connection (or access). Also, this may inclusively mean direct or indirect connection (or access) and integral or non-integral connection (or access).

Referring to FIGS. 1 and 2, the pixel PX may include sub-pixels SPX1 to SPX3. For example, the pixel PX may include a first sub-pixel SPX1, a second sub-pixel SPX2, and a third sub-pixel SPX3.

Each of the sub-pixels SPX1 to SPX3 may emit light of a predetermined color. In some embodiments, the sub-pixels SPX1 to SPX3 may emit lights of different colors. In an embodiment, the first sub-pixel SPX1 may emit light of a first color, the second sub-pixel SPX2 may emit light of a second color, and the third sub-pixel SPX3 may emit light of a third color. For example, the first sub-pixel SPX1 may be a red pixel emitting light of red, the second sub-pixel SPX2 may be a green pixel emitting light of green, and the third sub-pixel SPX3 may be a blue pixel emitting light of blue. However, the disclosure is not limited thereto.

In an embodiment, the first sub-pixel SPX1, the second sub-pixel SPX2, and the third sub-pixel SPX3 may have, as light sources, a light emitting element of the first color, a light emitting element of the second color, and a light emitting element of the third color, to emit lights of the first color, the second color, and the third color, respectively. In another embodiment, the first sub-pixel SPX1, the second sub-pixel SPX2, and the third sub-pixel SPX3 may have light emitting elements emitting light of the same color and include color conversion layers and/or color filters of different colors, which are disposed above the respective light emitting elements, to respectively emit lights of the first color, the second color, and the third color. However, the color, kind, and/or number of sub-pixels SPX1 to SPX3 constituting each pixel PX are not particularly limited. That is, the color of light emitted by each pixel PX may be variously changed.

Each of the first sub-pixel SPX1, the second sub-pixel SPX2, and the third sub-pixel SPX3 may have a planar rectangular, square or rhombic shape. For example, each of the first sub-pixel SPX1, the second sub-pixel SPX2, and the third sub-pixel SPX3 may have a rectangular planar shape having short sides in the first direction DR1 and long sides in the second direction DR2. Alternatively, in some embodiments, each of the first sub-pixel SPX1, the second sub-pixel SPX2, and the third sub-pixel SPX3 may have a square or rhombic shape including sides having the same length in the first direction DR1 and the second direction DR2. Although the sub-pixels SPX1, SPX2, SPX3 are shown to all have the same shape in the embodiments depicted, this is not a limitation and sub-pixels may have different shapes.

The sub-pixels SPX1 to SPX3 may be regularly arranged according to a stripe structure, a PENTILE™ structure, or the like. For example, the first, second, and third sub-pixels SPX1, SPX2, and SPX3 may be sequentially and repeatedly disposed along the first direction DR1. Also, the first, second, and third sub-pixels SPX1, SPX2, and SPX3 may be repeatedly disposed along the second direction DR2. At least one first sub-pixel SPX1, at least one second sub-pixel SPX2, and at least one third sub-pixel SPX3, which are disposed adjacent to each other, may constitute one pixel PX capable of emitting lights of various colors. However, the arrangement structure of the sub-pixels SPX1 to SPX3 is not limited thereto, and the sub-pixels SPX1 to SPX3 may be arranged in the display area DA in various structures and/or various manners.

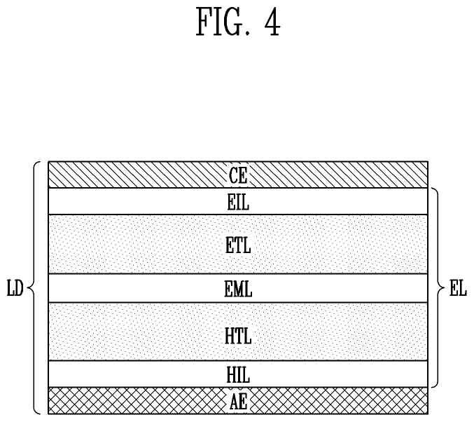

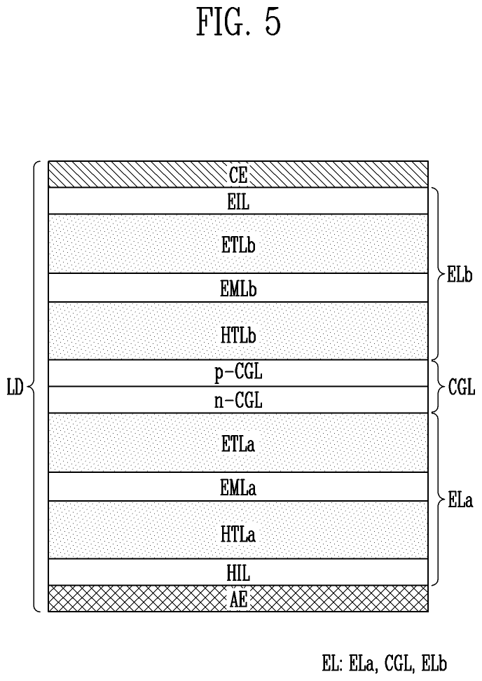

In an embodiment, each of the sub-pixels SPX1 to SPX3 may be configured as an active pixel. For example, each of the sub-pixels SPX1 to SPX3 may include at least one light source (e.g., a light emitting element LD shown in FIGS. 4 and 5) driven by a predetermined control signal (e.g., a scan signal and a data signal) and/or a predetermined power source (e.g., a first power source and a second power source). However, the kind, structure, and/or driving method of the sub-pixels SPX1 to SPX3, which can be applied to the display device, are not particularly limited.

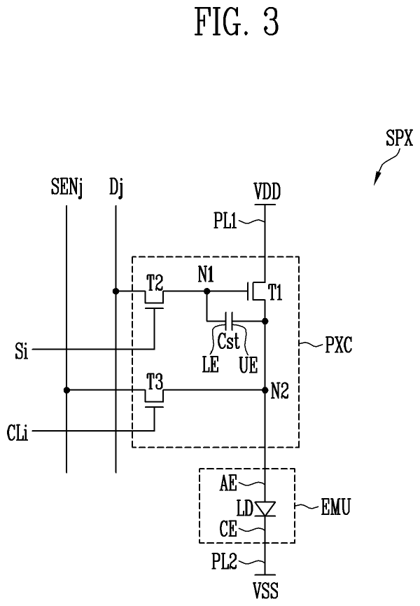

FIG. 3 is a circuit diagram illustrating an embodiment of a sub-pixel included in the pixel shown in FIG. 2.

A sub-pixel SPX shown in FIG. 3 may be any one of the sub-pixels SPX1 to SPX3 shown in FIG. 2, and sub-pixels SPX1 to SPX3 arranged in a display area of each display device DD may be configured substantially identically or similarly to one another.

For convenience of description, a sub-pixel SPX located on an ith pixel row (or ith horizontal line) and a jth pixel column will be illustrated in FIG. 3 (i and j are natural numbers).

Referring to FIG. 3, the sub-pixel SPX may include a light emitting unit EMU which generates light with a luminance corresponding to a data signal. Also, the sub-pixel SPX may further include a pixel circuit PXC for driving the light emitting unit EMU.

The light emitting unit EMU may include a light emitting element LD connected between a first power line PL1 supplied with a voltage of a first driving power source VDD (or first power source) and a second power line PL2 supplied with a voltage of a second driving power source VSS (or second power source). In an embodiment, the light emitting unit EMU may include a light emitting element LD including a first pixel electrode AE connected to the first driving power source VDD via the pixel circuit PXC and the first power line PL1 and a second pixel electrode CE connected to the second driving power source VSS via the second power line PL2. The first pixel electrode AE may be an anode, and the second pixel electrode CE may be a cathode. The first driving power source VDD and the second driving power source VSS may have different potentials. A potential difference between the first and second driving power sources VDD and VSS may be set equal to or higher than a threshold voltage of the light emitting element LD during an emission period of a sub-pixel SPX.

When the sub-pixel SPX is located on an ith pixel row and a jth pixel column in the display area of the display device DD, the pixel circuit PXC of the sub-pixel SPX may be electrically connected to an ith scan line Si and a jth data line Dj. Also, the pixel circuit PXC may be electrically connected to an ith control line CLi and a jth sensing line SENj.

The above-described pixel circuit PXC may include first to third transistors T1, T2, and T3 and a storage capacitor Cst.

The first transistor T1 is a driving transistor for controlling a driving current applied to the light emitting element LD, and may be electrically connected between the first driving power source VDD and the light emitting element LD. Specifically, a first terminal of the first transistor T1 may be electrically connected to the first driving power source VDD through the first power line PL1, a second terminal of the first transistor T1 may be electrically connected to a second node N2, and a gate electrode of the first transistor T1 may be electrically connected to a first node N1. The first transistor T1 may control an amount of driving current applied from the first driving power source VDD to the light emitting element LD through the second node N2 according to a voltage applied to the first node N1. In an embodiment, the first terminal of the first transistor T1 may be a drain electrode, and the second terminal of the first transistor T1 may be a source electrode. However, the disclosure is not limited thereto. In some embodiments, the first terminal may be the source electrode, and the second terminal may be the drain electrode.

The second transistor T2 is a switching transistor which selects a sub-pixel SPX in response to a scan signal and activates the sub-pixel SPX, and may be electrically connected between a data line Dj (e.g., the jth data line) and the first node N1. A first terminal of the second transistor T2 may be electrically connected to the data line Dj, a second terminal of the second transistor T2 may be electrically connected to the first node N1 (or the gate electrode of the first transistor T1), and a gate electrode of the second transistor T2 may be electrically connected to a scan line Si (or the ith scan line). The first terminal and the second terminal of the second transistor T2 are different terminals. For example, when the first terminal is a drain electrode, the second terminal may be a source electrode.

The second transistor T2 may be turned on when a scan signal having a gate-on voltage (e.g., a high level voltage) is supplied from the scan line Si, to electrically connect the data line Dj and the first node N1 to each other. The first node N1 is a point at which the second terminal of the second transistor T2 and the gate electrode of the first transistor T1 are connected to each other, and the second transistor T2 may transfer a data signal to the gate electrode of the first transistor T1.

The third transistor T3 may electrically connect the first transistor T1 to a sensing line SENj (e.g., the jth sensing line), to acquire a sensing signal through the sensing line SENj, and detect a characteristic of the sub-pixel SPX, including a threshold voltage of the first transistor T1, and the like, by using the sensing signal. Information on the characteristic of the sub-pixel SPX may be used to convert image data such that a characteristic deviation between sub-pixels SPX can be compensated. A second terminal of the third transistor T3 may be electrically connected to the second terminal of the first transistor T1, a first terminal of the third transistor T3 may be electrically connected to the sensing line SENj, and a gate electrode of the third transistor T3 may be electrically connected to a control line CLi (e.g., the ith control line). The first terminal may be a drain electrode, and the second terminal may be a source electrode.

The third transistor T3 is an initialization transistor capable of initializing the second node N2, and may be turned on when a sensing control signal is supplied from the control line CLi, to transfer a voltage of an initialization power source to the second node N2. Accordingly, the storage capacitor Cst electrically connected to the second node N2 can be initialized.

The storage capacitor Cst may include a lower electrode LE (or first storage electrode) and an upper electrode UE (or second storage electrode). The lower electrode LE may be electrically connected to the first node N1, and the upper electrode UE may be electrically connected to the second node N2. The storage capacitor Cst charges a data voltage corresponding to a data signal supplied to the first node N1 during one frame period. Accordingly, the storage capacitor Cst can store a voltage corresponding to a difference between a voltage of the gate electrode of the first transistor T1 and a voltage of the second node N2.

Although an embodiment in which the first to third transistors T1 to T3 are all N-type transistors is disclosed in FIG. 3, the disclosure is not limited thereto. For example, at least one of the above-described first to third transistors T1 to T3 may be replaced with a P-type transistor. The structure of the pixel circuit PXC may be variously modified and embodied.

FIG. 4 is a sectional view illustrating an embodiment of the light emitting element shown in FIG. 3. FIG. 5 is a sectional view illustrating another embodiment of the light emitting element shown in FIG. 3.

Referring to FIG. 4, a light emitting element LD may include a first pixel electrode AE, an organic light emitting part EL, and a second pixel electrode CE, which are sequentially stacked.

In an embodiment, the organic light emitting part EL may be provided on the first pixel electrode AE. The organic light emitting part EL may have a multi-layer thin film structure including a plurality of light generation layers. The organic light emitting part EL may include a hole injection layer HIL, a hole transport layer HTL, a light emitting layer EML, an electron transport layer ETL, and an electron injection layer EIL, which are sequentially stacked.

The hole injection layer HIL may be an organic layer disposed between the first pixel electrode AE and the hole transport layer HTL to allow holes to be smoothly injected into the light emitting layer EML from the first pixel electrode AE. The hole transport layer HTL may be disposed on the hole injection layer HIL and the light emitting layer EML, to perform a function of receiving holes provided from the first pixel electrode AE and transporting the holes to the light emitting layer EML.

The electron injection layer EIL may be disposed between the electron transport layer ETL and the second pixel electrode CE. The electron transport layer ETL may be disposed on the light emitting layer EML, to perform a function of receiving electrons provided from the second pixel electrode CE and transporting the electrons to the light emitting layer EML.

The light emitting layer EML is an area in which light is generated by a combination of electrons and holes, which are supplied from the first pixel electrode AE and the second pixel electrode CE. The light emitting layer EML may include an organic light emitting material such as a high molecular organic material or a low molecular organic material, which emits light of a predetermined color. For example, the light emitting layer EML may be provided with an organic material emitting blue light. However, the disclosure is not limited thereto. In an embodiment, the light emitting layer EML may be provided with an organic material emitting red or green light, or be provided with an inorganic material or a quantum dot.

In an embodiment, the second pixel electrode CE may be integrally provided. The second pixel electrode CE may be disposed on the organic light emitting part EL. The second pixel electrode CE may be integrally formed in light emitting elements.

Referring to FIG. 5, a light emitting element LD may include a first pixel electrode AE, an organic light emitting part EL, and a second pixel electrode CE.

The organic light emitting part EL may include a plurality of light generation layers. In an embodiment, the organic light emitting part EL may include a first organic light emitting part ELa, a charge generation layer CGL, and a second organic light emitting part ELb. The first pixel electrode AE, the first organic light emitting part ELa, the charge generation layer CGL, the second organic light emitting part ELb, and the second pixel electrode CE may be sequentially stacked.

The first organic light emitting part ELa may be provided in a structure in which a hole injection layer HIL, a first hole transport layer HTLa, a first organic light emitting layer EMLa, and a first electron transport layer ETLa are sequentially stacked. The second organic light emitting part ELb may be provided in a structure in which the second hole transport layer HTLb, a second organic light emitting layer EMLb, a second electron transport layer ETLa, and an electron injection layer EIL are sequentially stacked.

In an embodiment, a buffer layer (not shown) may be disposed on the first organic light emitting layer EMLa and the second organic light emitting layer EMLb. The buffer layer may include an electron transport compound.

The charge generation layer CGL may perform a function of supplying charges to the first organic light emitting part ELa and the second organic light emitting part ELb. The charge generation layer CGL may include an n-type charge generation layer n-CGL for supplying charges to the first organic light emitting part ELa and a p-type charge generation layer p-CGL for supplying holes to the second organic light emitting part ELb. The n-type charge generation layer n-CGL may include a metal material as a dopant.

In FIG. 5, it has been illustrated that the light emitting element LD is provided such that two organic light emitting parts ELa and ELb of the light emitting element LD are stacked. However, the disclosure is not limited thereto. For example, the light emitting element LD may be provided such that three or four or more organic light emitting parts are stacked in the light emitting element LD.

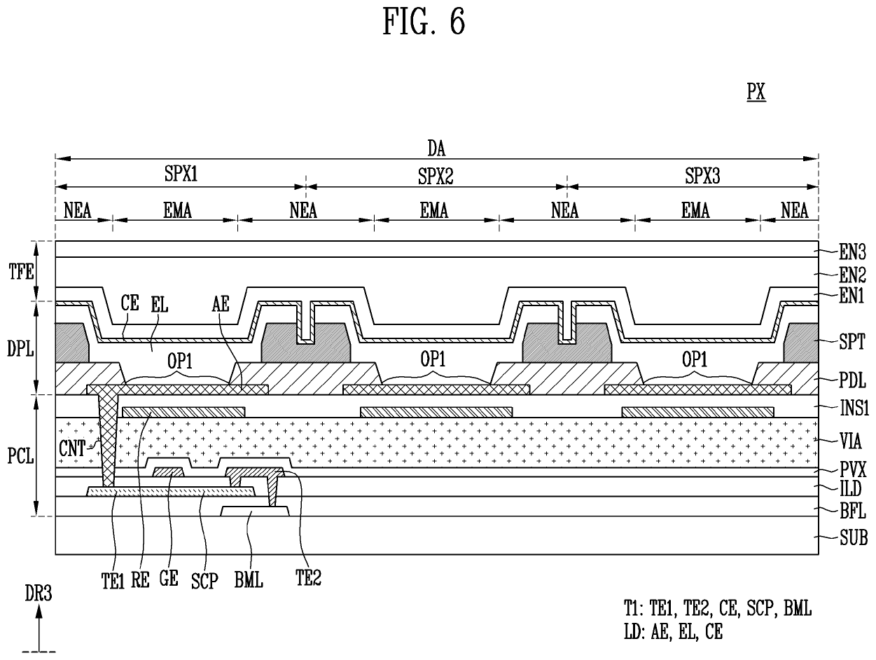

FIG. 6 is a sectional view illustrating an embodiment of a pixel including the light emitting element shown in FIG. 4 or 5.

Referring to FIG. 6, a stacked structure of a pixel PX is simplified and illustrated, such as that each electrode is illustrated as an electrode having a signal layer and each insulating layer is illustrated as an insulating layer provided as a single layer, but the disclosure is not limited thereto.

The pixel PX shown in FIG. 6 may include first to third sub-pixels SPX1 to SPX3. The first to third sub-pixels SPX1 to SPX3 may be disposed in the display area DA. The display area DA may include an emission area EMA and a non-emission area NEA.

In an embodiment, each of the first to third sub-pixels SPX1 to SPX3 may include a substrate SUB, a pixel circuit layer PCL, a display element layer DPL, and an encapsulation layer TFE.

Hereinafter, for convenience of description, the first sub-pixel SPX1 will be mainly described, and embodiments of the first sub-pixel SPX1 may be equally applied to the other sub-pixels.

The substrate SUB may include a transparent insulating material to allow light to be transmitted therethrough. The substrate SUB may be a rigid substrate or a flexible substrate.

Circuit elements (e.g., the first to third transistors T1 to T3 shown in FIG. 3) and signal lines electrically connected to the circuit elements may be disposed in the pixel circuit layer PCL. A light emitting element LD electrically connected to circuit elements may be disposed in the display element layer DPL.

A lower auxiliary electrode BML may be disposed on the substrate SUB. The lower auxiliary electrode BML may serve as a path along which an electrical signal is moved. In an embodiment, the lower auxiliary electrode BML may overlap with a first transistor T1.

A buffer layer BFL may be disposed on the substrate SUB. The buffer layer BFL may cover the lower auxiliary electrode BML. The buffer layer BFL may prevent an impurity from being diffused from the outside. The buffer layer BFL may prevent an impurity from being diffused into the first transistor T1 provided on the substrate SUB, and improve the flatness of the substrate SUB. The buffer layer BFL may be provided as a single layer, but be provided as a multi-layer. The buffer layer BFL may be an inorganic insulating layer including an inorganic material. The inorganic insulating layer may include, for example, at least one of silicon nitride (SiNₓ), silicon oxide (SiOₓ), and silicon oxynitride (SiOₓN_{y}), an a metal oxide such as aluminum oxide (AIOₓ). When the buffer layer BFL is provided as the multi-layer, layers may be formed of the same material or be formed of different materials. The buffer layer BFL may be omitted in some cases.

The first transistor T1 may include a semiconductor pattern SCP, a gate electrode GE, a first terminal TE1, and a second terminal TE2. The first terminal TE1 may be any one of a source electrode and a drain electrode, and the second terminal TE2 may be the other of the source electrode and the drain electrode. In an embodiment, when the first terminal TE1 is the drain electrode, the second terminal TE2 may be the source electrode.

The semiconductor pattern SCP may be provided and/or formed on the buffer layer BFL. The semiconductor pattern SCP may include a first contact region in contact with the first terminal TE1, a second contact region in contact with the second terminal TE2, and a channel region between the first contact region and the second contact region. The channel region may overlap with the gate electrode GE of the first transistor T1. The semiconductor pattern SCP may be a semiconductor pattern made of amorphous silicon, poly-silicon, low temperature poly-silicon, an oxide semiconductor, an organic semiconductor, or the like. The channel region may be, for example, an intrinsic semiconductor as a semiconductor pattern undoped with an impurity. The first contact region and the second contact region may correspond to a semiconductor pattern doped with the impurity. In an embodiment, the first terminal TE1 may be electrically connected to the light emitting element LD through a separate connection means.

An interlayer insulating layer ILD may be provided and/or formed over the semiconductor pattern SCP. The interlayer insulating layer ILD may be an inorganic insulating layer including an inorganic material. The interlayer insulating layer ILD may include the same material as the buffer layer BFL, or include at least one material selected from the materials exemplified as the material constituting the buffer layer BFL. In an embodiment, the interlayer insulating layer ILD may be provided as an organic insulating layer including an organic material. The interlayer insulating layer ILD may be provided as a single layer, but be provided as a multi-layer including at least two layers.

The gate electrode GE may be provided and/or formed on the interlayer insulating layer ILD to correspond to the channel region of the semiconductor pattern SCP. The gate electrode GE may be provided over the interlayer insulating layer ILD to overlap with the channel region of the semiconductor pattern SCP. The gate electrode GE may be formed as a single layer including one selected from the group consisting of copper (Cu), molybdenum (Mo), tungsten (W), aluminum neodymium (AlNd), titanium (Ti), aluminum (Al), silver (Ag), and any alloy thereof or a mixture thereof, or be formed in a double- or multi-layer structure including molybdenum (Mo), titanium (Ti), copper (Cu), aluminum (Al) or silver (Ag), which is a low-resistance material so as to decrease wiring resistance.

The second terminal TE2 may be provided and/or formed on the interlayer insulating layer ILD to be in contact with the second contact region of the semiconductor pattern SCP through a contact hole penetrating the interlayer insulating layer ILD. The second terminal TE2 may be in contact with the lower auxiliary electrode BML through a contact hole penetrating the interlayer insulating layer ILD and the buffer layer BFL. The first terminal TE1 and the second terminal TE2 may include the same material as the gate electrode GE, or include at least one material selected from the materials exemplified as the material constituting the gate electrode GE.

In the above-described embodiment, it has been illustrated that the first terminal TE1 of the first transistor T1 may be disposed in a region adjacent to the channel region of the semiconductor pattern SCP, and the second terminal TE2 of the first transistor T1 is electrically connected to the semiconductor pattern SCP through a contact hole penetrating the interlayer insulating layer ILD. However, the disclosure is not limited thereto. In some embodiments, the first terminal TE1 may be electrically connected to the semiconductor pattern SCP through a contact hole penetrating the interlayer insulating layer ILD, and the second terminal TE2 may be disposed in a region adjacent to the channel region of the semiconductor pattern SCP.

A protective layer PXV may be provided and/or formed over the first transistor T1. The protective layer PVX may be provided in a form including an inorganic insulating layer disposed on an organic insulating layer or an organic insulating layer disposed on an inorganic insulating layer. The inorganic insulating layer may include, for example, at least one of silicon oxide (SiOₓ), silicon nitride (SiNₓ), silicon oxynitride (SiOₓN_{y}), and a metal oxide such as aluminum oxide (AIOₓ). The organic insulating layer may include, for example, at least one of acrylic resin, epoxy resin, phenolic resin, polyamide resin, polyimide resin, unsaturated polyester resin, poly-phenylene ether resin, poly-phenylene sulfide resin, and benzocyclobutene resin.

A via layer VIA may be entirely provided and/or formed on the protective layer PVX. The via layer VIA may be an inorganic insulating layer including an inorganic material.

Reflective electrodes RE may be disposed on the via layer VIA. The reflective electrodes RE may be disposed on the via layer VIA, respectively corresponding to the first to third sub-pixels SPx1 to SPX3. In an embodiment, the reflective electrodes RE may be disposed on the via layer while being spaced apart from each other in a direction intersecting a third direction DR3.

The reflective electrodes RE may reflect light emitted in an organic light emitting part EL of the light emitting element LD in the third direction DR3. The reflective electrodes RE may include a metal material having excellent reflexibility. For example, the reflective electrodes RE may be made of a material such as aluminum (Al), titanium (Ti), silver (Ag), silver alloy (Ag alloy), copper (Cu), or magnesium-silver alloy (Mg—Ag), but the disclosure is not limited thereto.

In FIG. 6, the reflective electrodes RE may be disposed at different heights. For example, each of the reflective electrodes RE included in the first to third sub-pixels SPX1 to SPX3 may be disposed at a position for implementing a micro cavity effect. Distances between organic light emitting parts EL and the reflective electrodes RE, which are respectively disposed in the first to third sub-pixels SPX1 to SPX3, are adjusted, thereby improving the light emission efficiency of the first to third sub-pixels SPX1 to SPX3.

An inorganic layer INS1 may be entirely disposed over the reflective electrodes RE. The inorganic layer INS1 may be disposed between the via layer VIA and the light emitting element LD. The inorganic layer INS1 may serve as a cavity control layer which amplifies light emitted in the organic light emitting part EL and improves light emission efficiency. The inorganic layer INS1 may be formed in a structure disposed between the reflective electrodes RE and first pixel electrodes AE to implement micro cavities. Although a case where the inorganic layer INS1 on the via layer VIA has a planar upper surface is illustrated in FIG. 6, the disclosure is not limited thereto. For example, the inorganic layer INS1 may have different thicknesses with respect to the first to third sub-pixels SPX1 to SPX3 such that each of the first to third sub-pixels SPX1 to SPX3 implement a micro cavity corresponding to light emitted in the corresponding sub-pixel.

Each of the interlayer insulating layer ILD, the protective layer PVX, the via layer VIA, and the inorganic layer INS1 may be partially removed to form a contact part CNT. The first terminal TE1 may be electrically connected to the light emitting element LD through a contact part CNT.

The display element DPL may be provided and/or formed on the inorganic layer INS1. The display element layer DPL may include the light emitting element LD, a pixel defining layer PDL, and a separator SPT.

The light emitting element LD may include the first pixel electrode AE, the organic light emitting part EL, and a second pixel electrode CE. The light emitting element LD may be electrically connected to a pixel circuit (e.g., the pixel circuit PXC shown in FIG. 2) of a corresponding pixel.

The first pixel electrodes AE may be disposed on the inorganic layer INS1. The first pixel electrodes AE may be provided and/or formed on the inorganic layer INS1 of a corresponding pixel. The first pixel electrode AE may be an anode electrode of the light emitting element LD. The first pixel electrode AE may be electrically connected to the first terminal TE1 through a corresponding contact part CNT.

Each of the first pixel electrodes AE may be made of a conductive material (or substance). The conductive material may include an opaque metal. The opaque metal may include, for example, metals such as silver (Ag), magnesium (Mg), aluminum (Al), platinum (Pt), palladium (Pd), gold (Au), nickel (Ni), neodymium (Nd), iridium (Ir), chromium (Cr), titanium (Ti), and alloys thereof. However, the material of each of the first pixel electrodes AE is not limited to the above-described embodiment. In some embodiments, the first pixel electrode AE may include a transparent conductive material (or substance). The transparent conductive material (or substance) may include a conductive oxide such as indium tin oxide (ITO), indium zinc oxide (IZO), zinc oxide (ZnO), indium gallium zinc oxide (IGZO), or indium tin zinc oxide (ITZO), a conductive polymer such as poly (3,4-ethylenedioxythiophene (PEDOT), and the like. When the first pixel electrode AE may include a transparent conductive material (or substance), a separate conductive layer may be added, which is made of an opaque metal for reflecting light emitted in the organic light emitting part EL in an image display direction of a display device (e.g., the display device DD shown in FIG. 1) (or toward the encapsulation layer TFE). The first pixel electrode AE may be located in the emission area EMA.

The pixel defining layer PDL may be an organic insulating layer made of an organic material. In an embodiment, the pixel defining layer PDL may include a light absorption material or have a light absorber coated thereon, to absorb light introduced from the outside. For example, the pixel defining layer PDL may include a carbon-based black pigment. However, the disclosure is not limited thereto.

The pixel defining layer PDL may be partially opened to including a first opening OP1 exposing one area of each of the first pixel electrodes AE, and protrude in the third direction DR3 from the via layer VIA along the circumference of the emission area EMA. The pixel defining layer PDL may be disposed on the via layer VIA to define an area in which the organic light emitting part EL is in contact with the first pixel electrode AE. The organic light emitting part EL may be disposed on the first pixel electrode AE exposed by the first opening OP1.

The organic light emitting part EL may be located at an upper side of the first pixel electrode AE and an upper side of the pixel defining layer PDL in the first opening OP1 of the pixel defining layer PDL. However, the disclosure is not limited thereto, and the organic light emitting part EL may be located at only the upper side of the first pixel electrode AE in the first opening OP1 of the pixel defining layer PDL.

The organic light emitting part EL may have a multi-layer thin film structure including a light generation layer which generates light. The organic light emitting part EL may emit one light among light of red, light of green, and light of blue, but the disclosure is not limited thereto.

The separator SPT may be disposed on the pixel defining layer PDL. The separator SPT may be disposed in boundary areas between the first to third sub-pixels SPX1 to SPX3 adjacent to each other. A hole may be formed on a top surface of the separator SPT by a partial removal of the material that makes the separator SPT. The hole may physically indicate the boundary between organic light emitting parts EL disposed in adjacently located sub-pixels of the first to third sub-pixels SPX1 to SPX3. In the embodiment of FIG. 6, the light emitting part EL may be disposed on the separator SPT but not on the hole.

The separator SPT may include a metal material. For example, the separator SPT may include at least one of various metal materials including silver (Ag), magnesium (Mg), aluminum (Al), platinum (Pt), palladium (Pd), gold (Au), nickel (Ni), neodymium (Nd), iridium (Ir), chromium (Cr), titanium (Ti), molybdenum (Mo), copper (Cu), and the like, but the disclosure is not limited thereto. The separator SPT may include at least one conductive material among an alloy including the aforementioned metal material, a conductive oxide such as Indium Tin Oxide (ITO), Indium Zinc Oxide (IZO), Indium Tin Zinc Oxide (ITZO), Aluminum doped Zinc Oxide (AZO), Gallium doped Zinc Oxide (GZO), Zinc Tin Oxide (ZTO), or Gallium Tin Oxide (GTO), and a conductive polymer such as PEDOT, but the disclosure is not necessarily limited thereto.

Each organic light emitting part EL may be disposed in an area surrounded by the separator SPT.

The second pixel electrode CE may be disposed on the organic light emitting part EL. The second pixel electrode CE may be provided in a plate shape throughout the whole of the display area DA.

The second pixel electrode CE may be a thin film metal layer having a thickness enough to enable light emitted in each organic light emitting part EL to be transmitted therethrough. The second pixel electrode CE may be formed of a metal material to have a relatively thin thickness or be configured with a transparent conductive material. The second pixel electrode CE may include at least one of various transparent conductive materials including Indium Tin Oxide (ITO), Indium Zinc Oxide (IZO), Indium Tin Zinc Oxide (ITZO), Zinc Oxide (ZnO), Aluminum doped Zinc Oxide (AZO), Gallium doped Zinc Oxide (GZO), Zinc Tin Oxide (ZTO), and Gallium Tin Oxide (GTO), and to be substantially transparent or translucent to meet a predetermined transmittance. Accordingly, light emitted in the light emitting layer EML located on the bottom of the second pixel electrode CE can be emitted in an upper direction of the encapsulation layer TFE while passing through the second pixel electrode CE.

The encapsulation layer TFE may be entirely provided and/or formed on the second pixel electrode CE. The encapsulation layer TFE may block infiltration of moisture or oxygen introduced from the outside, thereby protecting the light emitting element LD. The encapsulation layer TFE may be a multi-layer film in which an inorganic layer and an organic layer are alternately disposed.

The encapsulation layer TFE may include first to third protective layers EN1 to EN3 sequentially located on the second pixel electrode CE. The first protective layer EN1 may be located on the display element layer DPL (or the second pixel electrode CE), thereby being entirely disposed in the display area DA. Each of the first protective layer EN1 and the third protective layer EN3 may be configured with an inorganic layer including an inorganic material, and the second protective layer EN2 may be configured with an organic layer including an organic material.

A color filter layer (not shown) may be further disposed on the encapsulation layer TFE. The color filter layer may include first to third color filters to respectively correspond to the first to third sub-pixels SPX1 to SPX3. The color filter layer may convert white light emitted from the organic light emitting part EL of the light emitting element LD into light of a specific color.

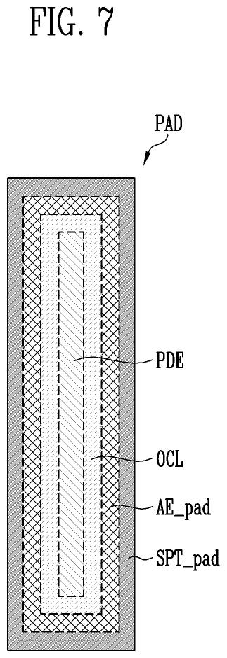

FIG. 7 is a plan view illustrating an embodiment of the pad area shown in FIG. 1.

Referring to FIG. 7, a pad PAD may be provided and/or formed in a pad area (e.g., the pad area PDA shown in FIG. 1). Some of components constituting the pad PAD are illustrated in FIG. 7.

Referring to FIG. 1 and FIG. 7, the pad area PDA may be disposed at one side of a substrate (e.g., the substrate SUB shown in FIG. 1). The pad PAD may be connected to an end of each of signal transfer lines connected to a pixel circuit (e.g., the pixel circuit PXC shown in FIG. 3). Although one pad PAD is illustrated in FIG. 7, a plurality of pads may be disposed in the pad area PDA. For example, the plurality of pads may be disposed along a plurality of rows arranged along the first direction DR1 and a plurality of columns arranged along the second direction DR2. The pad PAD may be disposed in a roughly rectangular shape to extend in the second direction DR2, but the disclosure is not limited thereto. For example, the pad PAD has a roughly rectangular shape, and may be arranged to extend along a direction oblique with respect to the second direction DR2.

In an embodiment, the pad PAD may include a pad electrode PDE, a pad pixel electrode AE_pad, and a separator SPT_pad. The pad electrode PDE, the pad pixel electrode AE_pad, and the separator SPT_pad may overlap with each other in plan view. The pad electrode PDE may be electrically connected to the pad pixel electrode AE_pad and the separator SPT_pad to receive a signal transferred from an external driving element. That is, the pad electrode PDE, the pad pixel electrode AE_pad, and the separator SPT_pad may form one conductive structure.

In an embodiment, the pad electrode PDE may be connected to internal lines connected to the pixel circuit (e.g., the pixel circuit PXC shown in FIG. 3). The pad electrode PDE may be formed in a via layer (e.g., the via layer VIA shown in FIG. 6) extending to the pad area PDA to be surrounded by a barrier layer OCL.

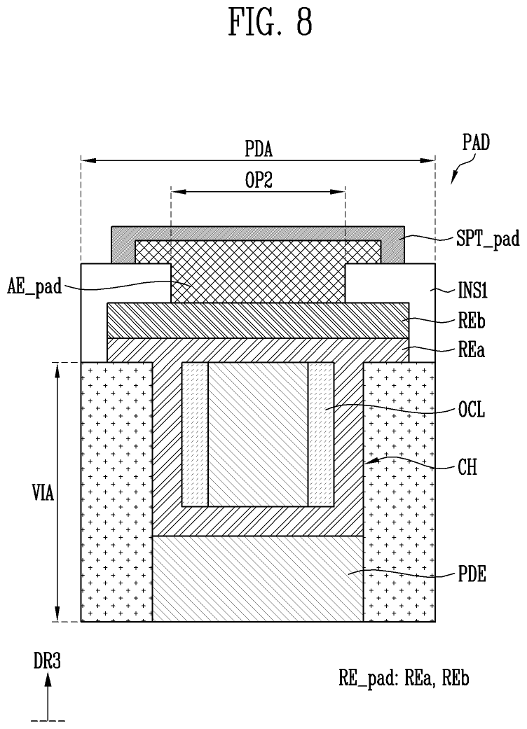

In an embodiment (e.g., the embodiment of FIG. 8), the pad pixel electrode AE_pad may be disposed on the pad electrode PDE (e.g., in the third direction DR3). The pad pixel electrode AE_pad may be formed through the same process as first pixel electrodes (e.g., the first pixel electrodes AE shown in FIG. 6) formed in a display area (e.g., the display area DA shown in FIG. 6). In an embodiment, the pad pixel electrode AE_pad may include a metal compound. For example, the pad pixel electrode AE_pad may include titanium nitride (TiN).

In an embodiment (e.g., the embodiment of FIG. 8), the separator SPT_pad may be disposed directly on the pad pixel electrode AE_pad. The separator SPT_pad may be disposed in the pad area PDA to be provided and/or formed as a separator (e.g., the separator SPT shown in FIG. 6) disposed in the display area (e.g., the display area DA shown in FIG. 6) extends. As the separator SPT_pad is disposed in the pad area PDA, the separator SPT_pad is not covered by an insulating layer but exposed.

FIG. 8 is a sectional view illustrating an embodiment of the pad area shown in FIG. 1.

Referring to FIG. 8, some components disposed in a display area (e.g., the display area DA shown in FIG. 6) may be disposed to extend in a pad area PDA. Insulating layers included in a pixel circuit layer (e.g., the pixel circuit layer PCL shown in FIG. 6) may extend in the pad area PDA. In the disclosure, a reflective electrode disposed in the pad area PDA among reflective electrodes RE is designated as a pad reflective electrode RE_pad, a first pixel electrode disposed in the pad area PDA among first pixel electrodes AE is designated as a pad pixel electrode AE_pad, and a separator disposed in the pad area PDA among separators SPT is designated as a separator SPT_pad.

In an embodiment, a pad electrode PDE may be disposed in a contact hole CH penetrating a via layer VIA in the third direction DR3. The pad electrode PDE may include a metal material. For example, the pad electrode PDE may include tungsten (W), titanium (Ti), aluminum (Al) or copper (Cu). In an embodiment, at least one side surface may be surrounded by a barrier layer OCL. When the pad electrode PDE is in direct contact with the via layer VIA in the contact hole CH, oxidation may be performed by reactivity between materials, and therefore, the barrier layer OCL may surround at least one side surface of the pad electrode PDE to protect the pad electrode PDE. In an embodiment, the barrier layer OCL may include a metal compound such as tungsten nitride (WN), titanium nitride (TiN), or tantalum nitride (TaN).

In an embodiment, the pad reflective electrode RE_pad may be disposed on the via layer VIA. The pad reflective electrode RE_pad may overlap with the pad electrode PDE exposed through the contact hole CH.

In an embodiment, the pad reflective electrode RE_pad may include a first pad reflective electrode Rea and a second pad reflective electrode REb. The pad reflective electrode RE_pad may include a metal material. The first pad reflective electrode REa may include a first conductive material, and the second pad reflective electrode REb may include a second conductive material different from the first conductive material. For example, the first pad reflective electrode REa may include titanium (Ti), and the second pad reflective electrode REb may include aluminum (Al). The first pad reflective electrode REa and the second pad reflective electrode REb may be sequentially disposed on the via layer VIA.

In an embodiment, the first pad reflective electrode REa may be disposed directly on the via layer VIA to overlap with the pad electrode PDE. The first pad reflective electrode REa may be electrically connected to the pad electrode PDE. In an embodiment, the first pad reflective electrode REa may surround a side surface of the barrier layer OCL in the contact hole CH. That is, at least one side surface of the pad electrode PDE may be surrounded by the barrier layer and the first pad reflective layer REa, thereby being covered with double layers.

In an embodiment, the second pad reflective electrode REb may be disposed directly on the first pad reflective electrode REa. For example, the first pad reflective electrode REa and the second pad reflective electrode REb may have heights different from each other in the third direction DR3. For example, a height of the second pad reflective electrode REb in the third direction DR3 may be higher than a height of the first pad reflective electrode REa in the third direction DR3.

In an embodiment, an inorganic layer INS1 may be disposed and/or provided to cover the pad reflective electrode RE_pad. The inorganic layer INS1 may be partially removed to make a second opening OP2 that extends to one area of the pad reflective electrode RE_pad. The pad pixel electrode AE_pad may be disposed on the second pad reflective electrode REb that forms the base of the second opening OP2 in the inorganic layer INS1. In an embodiment, the second opening OP2 is formed above the contact hole CH in plan view.

In an embodiment, the pad pixel electrode AE_pad may be disposed on the inorganic layer INS1 and in the second opening OP2 in the inorganic layer INS1. This way, th pad pixel electrode AE_pad may be electrically connected to the pad reflective electrode RE_pad.

In an embodiment, the separator SPT_pad may be disposed on the pad pixel electrode AE_pad to cover the pad pixel electrode AE_pad. The separator SPT_pad may be disposed and/or formed through the same process as the separator SPT disposed in the display area (e.g., the display area DA shown in FIG. 6), forming a continuous layer between the display area DA and the pad area PDA. In an embodiment, the separator SPT_pad is not covered by an insulating layer but may be exposed in the pad area PDA.

The display device in accordance with the embodiments of the disclosure includes the pad PAD configured by the pad reflective electrode RE_pad, the pad pixel electrode AE_pad, and the separator SPT_pad in the pad area PDA. Accordingly, a circuit test or the like on the pixel (or the sub-pixel) can be performed through the pad area PDA, and thus the reliability of the display device can be ensured.

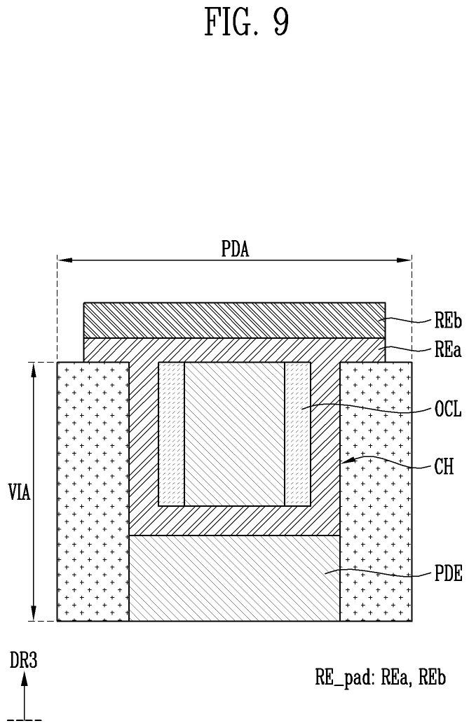

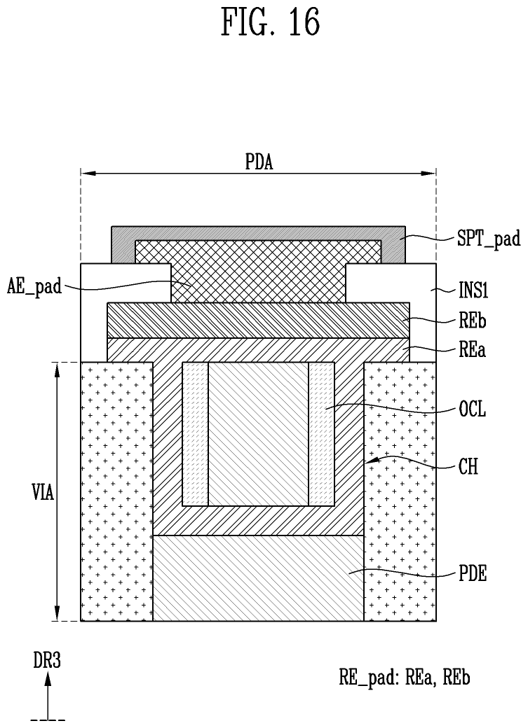

FIGS. 9 to 16 are schematic sectional views illustrating a method of manufacturing the display device in accordance with embodiments of the disclosure.

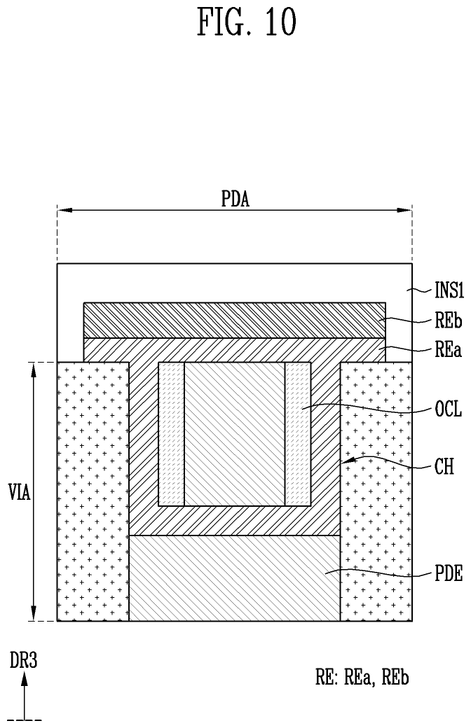

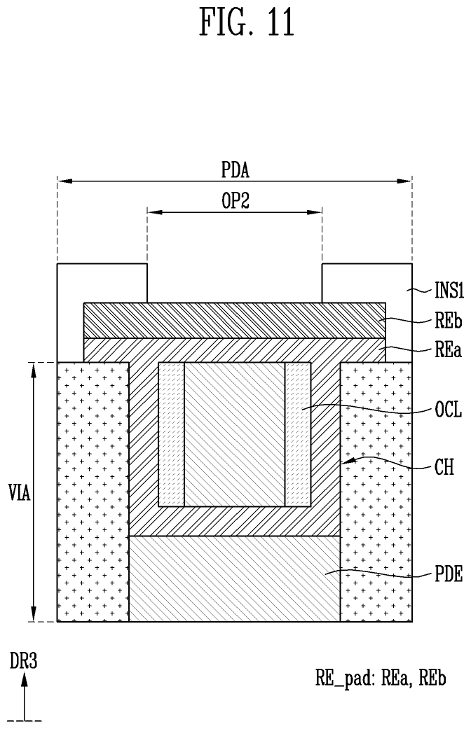

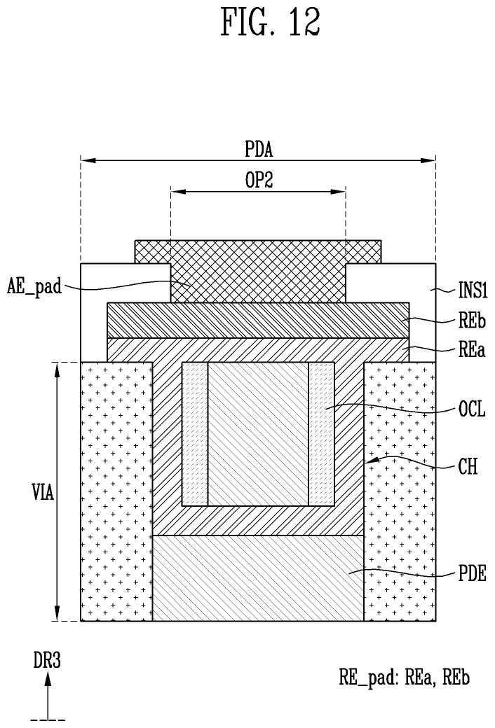

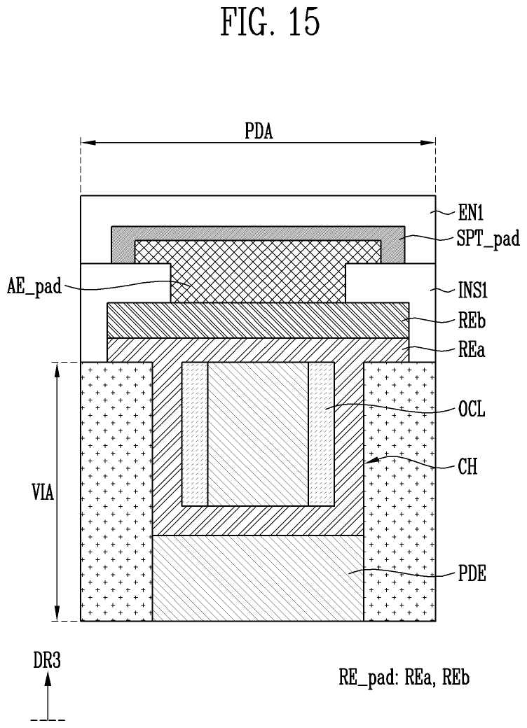

Referring to FIGS. 1, 6, and 9 to 16, the method of manufacturing the display device in accordance with the embodiments of the disclosure may include forming a substrate SUB including a display area DA and a pad area PDA located next to one side of the display area DA (see FIG. 1), forming a via layer VIA on the substrate SUB and forming a contact hole CH penetrating the via layer VIA in the pad area PDA (see FIG. 9), forming a pad electrode PDE in the contact hole CH (see FIG. 9), forming, on the via layer VIA, reflective electrodes RE spaced apart from each other in the first direction DR1 (see FIG. 6), forming an inorganic layer INS1 including a second opening OP2 extending to a reflective electrode RE_pad disposed in the pad area PDA among the reflective electrodes RE (see FIGS. 10 and 11), forming first pixel electrodes AE on the reflective electrodes RE (see FIGS. 6 and 12), and forming a separator SPT_pad on a pad pixel electrode AE_pad disposed in the pad area PDA among the first pixel electrodes AE (see FIG. 15).

Referring to FIGS. 1, 6, and 9, a via layer VIA may be formed on a substrate SUB including a display area DA and a pad area PDA. A contact hole CH penetrating the via layer VIA may be formed in the pad area PDA. A pad electrode PDE may be formed in the contact hole CH.

In an embodiment, the pad electrode PDE may include a metal material. At least one side surface of the pad electrode PDE, at which an oxidation reaction may occur when the pad electrode PDE is in direct contact with the contact hole CH, may be surrounded by a barrier layer OCL. The barrier layer OCL may include a metal compound.

Referring to FIGS. 6 and 9, reflective electrodes RE may be disposed on the via layer VIA in the display area DA while being spaced apart from each other in a first direction (e.g., the first direction DR1 shown in FIG. 1). In an embodiment, a pad reflective electrode RE_pad may be formed on the via layer VIA in the pad area PDA. The pad reflective electrode RE_pad may be formed through the same process as the reflective electrodes RE disposed in the display area DA.

In an embodiment, the pad reflective electrode RE_pad may include a first pad reflective electrode REa and a second pad reflective electrode REb. The first pad reflective electrode REa and the second pad reflective electrode REb may be sequentially formed on the via layer VIA. In an embodiment, the first pad reflective electrode REa may be formed to overlap with the pad electrode PDE that is at the bottom of the contact hole CH. In an embodiment, the first pad reflective electrode REa may extend to the inside of the contact hole CH to surround a side surface of the barrier layer OCL. In an embodiment, at least one side surface of the pad electrode PDE may be surrounded by the barrier layer OCL and the first pad reflective electrode REa. The second pad reflective electrode REb may be disposed on the first pad reflective electrode REa. In an embodiment, the pad reflective electrode RE_pad may include a conductive material. In an embodiment, the first pad reflective electrode REa may include a first conductive material, and the second pad reflective electrode REb may include a second conductive material different from the first conductive material. In an embodiment, the pad electrode PDE and the pad reflective electrode RE_pad may be electrically connected to each other.

Referring to FIGS. 6 and 10, an inorganic layer INS1 may be formed on the via layer VIA to cover the top and sides of reflective electrodes RE and the pad reflective electrode RE_pad.

Referring to FIG. 11, the via layer VIA may be partially removed to include a second opening OP2 exposing one area of the pad reflective electrode RE_pad. In an embodiment, the one area of the pad reflective electrode RE_pad at the bottom of the second opening OP2 may be exposed to the outside through the second opening OP2. In the embodiment depicted in FIG. 11, the second pad reflective electrode REb may be exposed through the second opening OP2.

Referring to FIGS. 6 and 12, first pixel electrodes AE may be formed on the reflective electrodes RE in the display area DA. A pad pixel electrode AE_pad may be formed on the pad reflective electrodes RE_pad in the pad area PDA. The pad pixel electrode AE_pad may be formed through the same process as the first pixel electrodes AE. The pad pixel electrode AE_pad and the first pixel electrodes AE may include the same material. In an embodiment, the pad pixel electrode AE_pad and the first pixel electrodes AE may include a metal compound.

In an embodiment, the first pixel electrodes AE may be formed on the inorganic layer INS1 to overlap with the reflective electrodes RE. The pad pixel electrode AE_pad may be disposed directly on the pad reflective electrode RE_pad. That is, the pad pixel electrode AE_pad may be formed on the inorganic layer INS1 to fill the second opening OP2 formed in the inorganic layer INS1. The pad pixel electrode AE_pad may be in contact with the second pad reflective electrode REb.

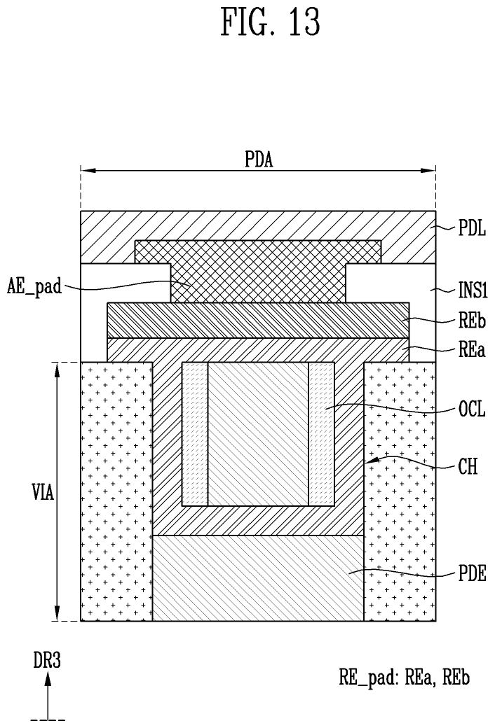

Referring to FIGS. 6 and 13, a pixel defining layer PDL may be formed in the display area DA and the pad area PDA. The pixel defining layer PDL may be formed on the first pixel electrodes AE and the pad pixel electrode AE_pad. The pixel defining layer PDL disposed in the display area DA may be partially removed to include a first opening OP1 above one area of each of the first pixel electrodes AE. The pixel defining layer PDL disposed in the pad area PDA may cover the pad pixel electrode AE_pad.

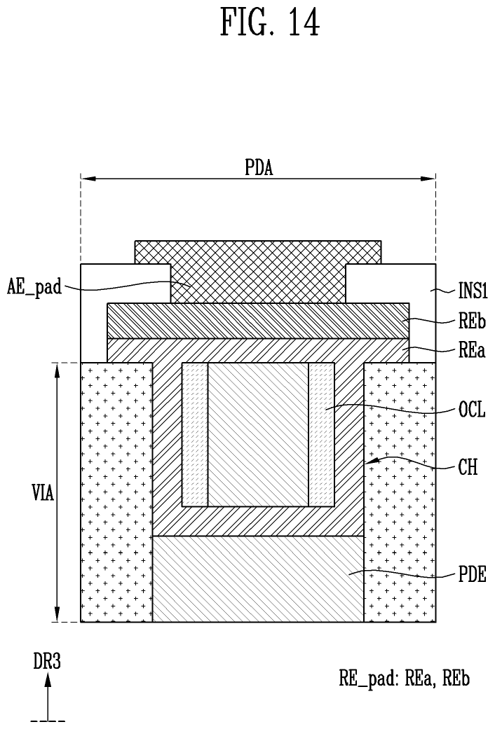

Referring to FIG. 14, the pixel defining layer PDL disposed in the pad area PDA may be removed. As the pixel defining layer PDL covering the pad pixel electrode AE_pad is removed, the pixel defining layer PDL disposed in the pad area PDA may expose the pad pixel electrode AE_pad to the outside.

Referring to FIGS. 6 and 15, a separator SPT may be formed on the pixel defining layer PDL in the display area DA. A separator SPT_pad may be formed on the pad pixel electrode AE_pad in the pad area PDA. The separators SPT and SPT_pad formed in the display area DA and the pad area PDA may be formed through the same process. The separator SPT may physically separate organic light emitting parts EL disposed in first, second, and third sub-pixels SPX1, SPX2, SPX3. The separator SPT_pad may be formed to cover the top and sides of pad pixel electrode AE_pad. In an embodiment, after the separator SPT is formed in the display area DA, the organic light emitting part EL and a second pixel electrode CE may be sequentially formed.

In an embodiment, a first protective layer EN1 may be formed over the second pixel electrode CE and the separator SPT_pad. The first protective layer EN1 may block infiltration of moisture or oxygen from the outside, thereby protecting a light emitting element LD. In an embodiment, the first protective layer EN1 disposed over the separator SPT_pad may be removed. The separator SPT_pad is not covered by an insulating layer but may be exposed.

In an embodiment, the pad electrode PDE, the pad reflective electrode RE_pad, the pad pixel electrode AE_pad, and the separator SPT_pad in the pad area PDA may be sequentially disposed in the third direction DR3 to constitute a single pad PAD. Accordingly, in the display device and the method of manufacturing the same in accordance with the embodiments of the disclosure, a test for checking whether a pixel circuit is electrically operating as intended in the pad area, and the like, can be easily performed. By providing a simple way to test a pixel circuit, the disclosure provides a way to improve the reliability of the display device.

In the display device and the method of manufacturing the same in accordance with the disclosure, a separator is provided so as to provide an organic light emitting part separated physically between neighboring sub-pixels disposed in the display area. The separator extends to the pad area to constitute, together with a pad pixel electrode and a pad reflective electrode, a pad in the pad area. Accordingly, in the display device and the method of manufacturing the same in accordance with the disclosure, a test for checking whether a pixel circuit is electrically operating as intended in the pad area, and the like, can be easily performed. By providing an easy way to test the pixel circuit, the disclosure provides a way to improve the reliability of the display device.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the disclosure as set forth in the following claims.

What is claimed is:

1. A display device comprising:
a substrate including a display area and a pad area located outside of the display area;
reflective electrodes disposed on the substrate and spaced apart from each other in a first direction, the reflective electrodes including a pad reflective electrode disposed in the pad area;
an inorganic layer disposed over the reflective electrodes;
first pixel electrodes disposed on the first inorganic layer, the first pixel electrodes including a pad pixel electrode disposed in the pad area;
a pixel defining layer including a first opening above each of the first pixel electrodes disposed in the display area; and
a separator disposed on the pixel defining layer of the display area and on the pad area,
wherein the inorganic layer includes a second opening extending to the pad reflective electrode,
wherein the pad pixel electrode is disposed in the second opening and contacts the pad reflective electrode at bottom of the second opening, and
wherein the separator continuously extends to the pad area from the display area to be disposed directly on the pad pixel electrode.

2. The display device of claim 1, wherein the first pixel electrodes overlap with the reflective electrodes.

3. The display device of claim 1, wherein the separator covers the pad pixel electrode.

4. The display device of claim 1, comprising:
a via layer disposed between the substrate and the reflective electrodes, the via layer having a contact hole in the pad area; and
a pad electrode electrically connected to the pad reflective electrode through the contact hole,
wherein the contact hole overlaps with the second opening.

5. The display device of claim 4, wherein the pad reflective electrode includes:
a first pad reflective electrode disposed on the via layer, the first pad reflective electrode including a first conductive material; and
a second pad reflective electrode disposed on the first pad reflective electrode, the second pad reflective electrode including a second conductive material different from the first conductive material.

6. The display device of claim 5, wherein the first pad reflective electrode covers the pad electrode and extends beyond the boundary of the pad electrode in plan view, and
wherein the via layer includes an inorganic material.

7. The display device of claim 6, wherein the first pad reflective electrode includes titanium (Ti), and
the second pad reflective electrode includes aluminum (Al).

8. The display device of claim 6, further comprising a barrier layer disposed between the first pad reflective electrode and the pad electrode in the contact hole,
wherein the barrier layer includes a metal compound.

9. The display device of claim 8, wherein the barrier layer includes titanium nitride (TIN).

10. The display device of claim 1, wherein the pixel defining layer is disposed only outside of the pad area.

11. The display device of claim 1, wherein the separator includes a metal material.

12. The display device of claim 1, further comprising:
an organic light emitting part disposed on the pixel defining layer and the separator in the display area, the organic light emitting part including a plurality of light generation layers; and
a second pixel electrode disposed on the organic light emitting part.

13. The display device of claim 12, further comprising first, second, and third protective layers sequentially disposed on the second pixel electrode in a third direction intersecting the first direction,
wherein the first, second, and third protective layers are disposed only outside of the pad area.

14. The display device of claim 13, wherein the organic light emitting part includes a hole injection layer, a hole transport layer, a light emitting layer, an electron transport layer, and an electron injection layer, which are sequentially disposed in the third direction.

15. A method of manufacturing a display device, the method comprising:
forming a substrate including a display area and a pad area located at one side of the display area;
forming a via layer on the substrate;
forming a contact hole through the via layer in the pad area;
forming a pad electrode in the contact hole;
forming pad reflective electrodes spaced apart from each other in a first direction on the via layer;
forming an inorganic layer;
partially removing sections of the inorganic layer to form a second opening above at least one of the pad reflective electrodes disposed in the pad area;
forming first pixel electrodes on the reflective electrodes; and
forming a separator on a pad pixel electrode disposed in the pad area among the first pixel electrodes.

16. The method of claim 15, wherein the display area includes first, second, and third sub-pixels, and
wherein the method further comprises:
forming a pixel defining layer on the first pixel electrodes in the display area and on the pad area; and
selectively removing the pixel defining layer from each of the first sub-pixel, the second sub-pixel, and the third sub-pixel in the display area and removing the pixel defining layer from the pad area.

17. The method of claim 16, wherein the partial removal of the pixel defining layer further includes forming a first opening exposing the first pixel electrodes, and
wherein the method further comprises sequentially forming an organic light emitting part and a second pixel electrode on the first pixel electrode that is exposed at the base of the first opening.

18. The method of claim 17, further comprising:
forming a first protective layer over the separator formed in the pad area and the second pixel electrode formed in the display area; and
removing the first protective layer formed in the pad area.

19. The method of claim 18, further comprising:
sequentially forming a second protective layer and a third protective layer in a third direction intersecting the first direction on the first protective layer in the display area,
wherein the first protective layer and the third protective layer include an inorganic material, and
the second protective layer includes an organic material.

20. The method of claim 15, wherein the forming of the pad reflective electrode disposed in the pad area includes:
forming a first pad reflective electrode including a first conductive material in an area overlapping with the contact hole on the via layer; and
forming a second pad reflective electrode including a second conductive material different from the first conductive material on the first pad reflective electrode.
